(19) United States
(12) Patent Application Publication
(10) Pub. No.: US 2024/0394639 A1
(43) Pub. Date: Nov. 28, 2024

(54) MARKET ADJUSTED DATA DRIVEN TEAM STRENGTH RATINGS FOR ACCURATE TOURNAMENT SIMULATION

(71) Applicant: Stats LLC, Chicago, IL (US)

(72) Inventors: Nils Sebastiaan Mackaij, Amsterdam (NL); Daniele Foroni, Chicago, IL (US); Yadir Lakehal, New York, NY (US); Robert Seidl, Munich (DE); Patrick Joseph Lucey, Chicago, IL (US)

(73) Assignee: Stats LLC, Chicago, IL (US)

(21) Appl. No.: 18/666,409

(22) Filed: May 16, 2024

Related U.S. Application Data
(60) Provisional application No. 63/503,633, filed on May 22, 2023.

(51) Int. Cl. G06Q 10/0639; G06F 30/20; G06Q 30/0201

(52) U.S. Cl. CPC G06Q 10/06393; G06F 30/20; G06Q 30/0201

(57) ABSTRACT

Embodiments disclosed herein generally relate to a system and method for updating a set of strength-based ratings for a sporting event using market information. The present embodiments provide a data-driven approach leveraging market information to derive an updated team strength prior to an upcoming event. For example, a prediction model can internally determine an initial team strength measurement. The prediction model can also obtain futures market information and update the initial team strength measurement using the futures market information.

### CROSS-REFERENCE TO RELATED APPLICATION(S)

This application claims the benefit of priority from U.S. Provisional Application No. 63/503,633, filed on May 22, 2023, which is hereby incorporated by reference in its entirety.

### FIELD OF THE DISCLOSURE

The present disclosure generally relates to a system and method for generating predictions for players or teams for a sporting event using an updated set of strength-based rating using market information.

### BACKGROUND

In many sports, such as soccer, teams can be ranked as part of a ranking system. For example, an international governing body of a sport (e.g., FIFA) can rank international soccer teams for an upcoming event, such as the World Cup.

However, such rankings can be a poor representation of team strength prior to the upcoming event. For instance, international teams may have irregularity in the status of the team roster, and there can be long periods of time (e.g., months) between matches of international teams. In many cases, national teams do not play very often. Further, many of the matches can be exhibition matches (or “friendlies”) and may not be representative of overall team strength. Such teams can also have more roster changes than other team types (e.g., club teams). This can result in the ratings based primarily on previous performances of a team not being an accurate representation of the strength of the team coming into the upcoming event.

### SUMMARY

Embodiments disclosed herein generally relate to a system and method for updating a set of strength-based ratings for a sporting event using market information. The present embodiments provide a data-driven approach leveraging market information to derive an updated team strength prior to an upcoming event. For example, a prediction model can internally determine an initial team strength measurement. The prediction model can also obtain futures market information and update the initial team strength measurement using the futures market information.

A first example embodiments provides a method of updating a set of strength-based ratings for a sporting event using market information. The method can be performed by a computing system as described herein. The method can include generating, using a prediction model, an initial set of strength ratings of each player or team associated with a sporting event. In some instances, each of the initial set of strength ratings include a metric indicating a predicted strength of each player or team that are part of the sporting event. The initial set of strength ratings can be generated at least based on historical player and team data. The method can also include obtaining a set of market information specifying at least a predicted likelihood of each player or team winning the sporting event. In some instances, the market information is obtained by one or more sources of market information. The method can also include generating, using the prediction model, an updated set of strength ratings using the set of market information. The updated set of strength ratings can be modified based on the set of market information to take into account any differences between the initial strength ratings and a probability of each team winning the sporting event provided by the market sources. The method can also include performing, by a simulation model, a number of simulations of the sporting event using the updated set of strength ratings to generate a set of predictions for each player or team that are part of the sporting event. The method can also include generating an output depicting the predictions of each player or team that are part of the sporting event. In some instances, the output includes an illustration of a bracket depicting an initial placement of each player or team in the sporting event, The output can further display the predictions of each player or team advancing to each stage of the sporting event or winning the sporting event. In some instances, the output includes a table of each player or team in the sporting event and the predictions of each player or team advancing to each stage of the sporting event or winning the sporting event.

In another example embodiment, a system for updating a set of strength-based ratings for a sporting event using market information. The system can include a processor and a memory having programming instructions stored thereon. The instructions, which, when executed by the processor, performs one or more operations. The operations can include identifying an occurrence of an upcoming sporting event. The operations can also include generating, using a prediction model, an initial set of strength ratings of each player or team associated with the sporting event. In some instances, the one or more operations further include identifying a change to a roster of one or more teams for the sporting event and, responsive to identifying the change, modifying the initial set of strength ratings of each player or team associated with the sporting event to account for the change to the roster of the one or more teams for the sporting event. In some instances, each of the initial set of strength ratings include a metric indicating a predicted strength of each player or team that are part of the sporting event. The initial set of strength ratings can be generated at least based on historical player and team data. The operations can also include obtaining a set of market information specifying any of a predicted likelihood of each player or team advancing to a stage of the sporting event or winning the sporting event. The operations can also include generating, using the prediction model, an updated set of strength ratings using the set of market information. The operations can also include performing, by a simulation model, a number of simulations of the sporting event using the updated set of strength ratings to generate a set of predictions for each player or team that are part of the sporting event. The set of predictions for each player or team that are part of the sporting event can include, for each player or team, a predicted likelihood of the player or team advancing to each stage of the sporting event and/or the player or team winning the sporting event. The operations can also include generating an output depicting the predictions of each player or team that are part of the sporting event.

In another example embodiment, a non-transitory computer readable medium including one or more sequences of instructions is provided. The instructions, when executed by the one or more processors, can cause the processor to perform processes. The processes can include generating, using a prediction model, an initial set of strength ratings of each player or team associated with a sporting event. The processes can also include obtaining market information from multiple sources specifying at least a predicted likelihood of each player or team winning the sporting event. In some instances, each of the initial set of strength ratings include a metric indicating a predicted strength of each player or team that are part of the sporting event, wherein the initial set of strength ratings are generated at least based on historical player and team data. The processes can also include combining data from each of the multiple sources of market information to generate a combined predicted likelihood of each player or team winning the sporting event. The processes can also include generating, using the prediction model, an updated set of strength ratings using the combined predicted likelihood of each player or team winning the sporting event. The processes can also include performing, by a simulation model, a number of simulations of the sporting event using the updated set of strength ratings to generate a set of predictions for each player or team that are part of the sporting event. The processes can also include generating an output depicting the predictions of each player or team that are part of the sporting event.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrated only typical embodiments of this disclosure and are therefore not to be considered limiting of its scope, for the disclosure may admit to other equally effective embodiments.

FIG. 1 is a block diagram illustrating a computing environment, according to example embodiments.

FIG. 2 is an example flow process for updating an initial set of rankings using market information, according to example embodiments.

FIG. 3 is an example output illustrating predictions for each team for an upcoming event, according to example embodiments.

FIG. 4 provides a first example output of predictions for an event, according to example embodiments.

FIG. 5 provides a second example output of predictions for an event, according to example embodiments.

FIG. 6 is a flow diagram of an example method of updating a set of strength-based ratings for a sporting event using market information, according to example embodiments.

FIG. 7A is a block diagram illustrating a computing device, according to example embodiments.

FIG. 7B is a block diagram illustrating a computing device, according to example embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In many sports, such as soccer, teams can be ranked as part of a ranking system. For example, an international governing body of a sport (e.g., FIFA) can rank international soccer teams for an upcoming event, such as the World Cup.

However, such rankings can be a poor representation of team strength prior to the upcoming event. For instance, international teams may have irregularity in the status of the team roster, and there can be long periods of time (e.g., months) between matches of international teams. In many cases, national teams do not play very often. Further, many of the matches can be exhibition matches (or “friendlies”) and may not be representative of overall team strength. Such teams can also have more roster changes than other team types (e.g., club teams). This can result in the ratings based primarily on previous performances of a team not being an accurate representation of the strength of the team coming into the upcoming event.

Other sources can provide differing estimates of team strength. For example, market information can include an estimate of overall team strength based on an assortment of factors specific to each source (e.g., individual player performance, roster changes, manager changes, analytical trends in previous matches). However, due to permutations for the upcoming event, such as the draw or bracket made for the tournament, many sources may not accurately take such information into account when ranking teams. These sources may also not predict a likelihood of each team winning a game/tournament based on a pathway of winning the tournament as dictated by the draw/bracket of the tournament.

The present embodiments provide a data-driven approach leveraging market information to derive an updated team strength prior to an upcoming event. For example, a prediction model can internally determine an initial team strength measurement. The prediction model can also obtain futures market information and update the initial team strength measurement using the futures market information.

The present embodiments can be applied to other sports that have such cold-start problems. For example, the present embodiments can be applied to sports with international tournaments (e.g., international basketball, Olympic tournaments) or tournaments where a court-surface changes (e.g., grass courts vs. clay courts in tennis), where ranking/seedings of players/teams may not accurately capture overall player/team strength for an upcoming event.

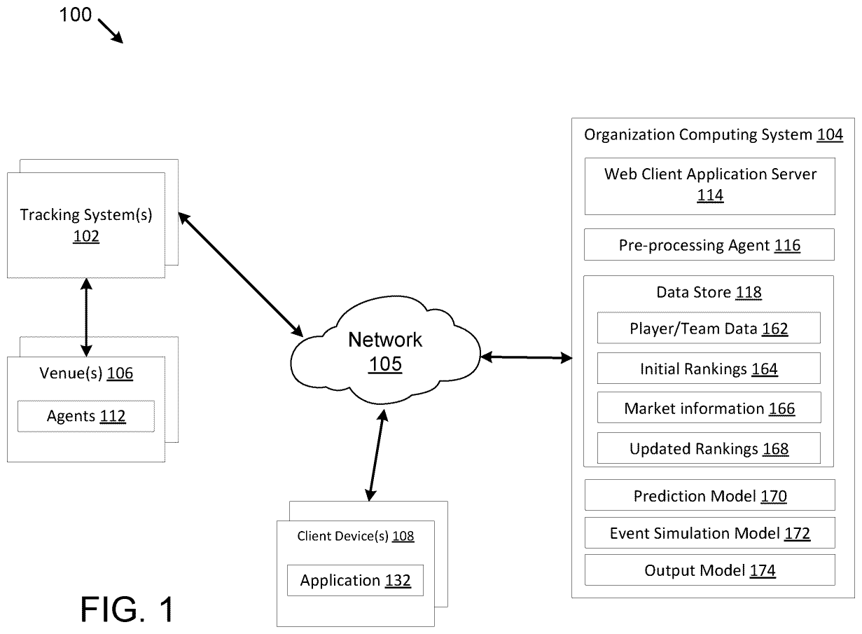

FIG. 1 is a block diagram illustrating a computing environment 100, according to example embodiments. Computing environment 100 may include tracking system 102, organization computing system 104, and one or more client devices 108 communicating via network 105.

Network 105 may be of any suitable type, including individual connections via the Internet, such as cellular or Wi-Fi networks. In some embodiments, network 105 may connect terminals, services, and mobile devices using direct connections, such as radio frequency identification (RFID), near-field communication (NFC), Bluetooth™, low-energy Bluetooth™ (BLE), Wi-Fi™, ZigBee™, ambient backscatter communication (ABC) protocols, USB, WAN, or LAN. Because the information transmitted may be personal or confidential, security concerns may dictate one or more of these types of connection be encrypted or otherwise secured. In some embodiments, however, the information being transmitted may be less personal, and therefore, the network connections may be selected for convenience over security.

Network 105 may include any type of computer networking arrangement used to exchange data or information. For example, network 105 may be the Internet, a private data network, virtual private network using a public network and/or other suitable connection(s) that enables components in computing environment 100 to send and receive information between the components of environment 100.

Tracking system 102 may be positioned in a venue 106. For example, venue 106 may be configured to host a sporting event that includes one or more agents 112. Tracking system 102 may be configured to record the motions of all agents (i.e., players) on the playing surface, as well as one or more other objects of relevance (e.g., ball, referees, etc.). In some embodiments, tracking system 102 may be an optically-based system using, for example, a plurality of fixed cameras. For example, a system of six stationary, calibrated cameras, which project the three-dimensional locations of players and the ball onto a two-dimensional overhead view of the court may be used.

In some embodiments, tracking system 102 may be a radio-based system using, for example, radio frequency identification (RFID) tags worn by players or embedded in objects to be tracked. Generally, tracking system 102 may be configured to sample and record, at a high frame rate (e.g., 25 Hz). Tracking system 102 may be configured to store at least player identity and positional information (e.g., (x, y) position) for all agents and objects on the playing surface for each frame in a game file.

Tracking system 102 may be configured to communicate with organization computing system 104 via network 105. Organization computing system 104 may be configured to manage and analyze the data captured by tracking system 102. Organization computing system 104 may include at least a web client application server 114, a pre-processing agent 116, a data store 118, a prediction model 170, an event simulation model 172, and an output model 174.

Each of pre-processing agent 116, prediction model 170, event simulation model 172, and output model 174 may be comprised of one or more software modules. The one or more software modules may be collections of code or instructions stored on a media (e.g., memory of organization computing system 104) that represent a series of machine instructions (e.g., program code) that implements one or more algorithmic steps. Such machine instructions may be the actual computer code the processor of organization computing system 104 interprets to implement the instructions or, alternatively, may be a higher level of coding of the instructions that is interpreted to obtain the actual computer code. The one or more software modules may also include one or more hardware components. One or more aspects of an example algorithm may be performed by the hardware components (e.g., circuitry) itself, rather as a result of the instructions.

In some embodiments, pre-processing agent 116 may be configured to process data retrieved from data store 118 prior to input to any of the prediction model 170, event simulation model 172, and output model 174.

Data store 118 may be configured to store various source of information. For example, the data store 118 can store player/team data 162, initial rankings 164, market information 166, and/or updated rankings 168. The player/team data 162 can include historical data relating to each player and/or team. The historical data can track metrics and trends of a player or team over time that can be used in generating strength-based rankings as described herein.

The initial rankings 164 can include an initial set of strength-based rankings generated by a prediction model 170. The initial rankings 164 can be based on player/team data 162 or other contextual information, such as a location or weather or condition type (e.g., grass or clay courts) for the upcoming event.

The market information 166 can include futures predictions for the upcoming event from one or more sources. Market information 166 can include predictions, odds, etc., specifying a predicted likelihood of a player/team advancing or winning the event. The market information 166 can be aggregated from multiple sources to generate an overall prediction from the market.

Updated rankings 168 can include the updated set of strength-based rankings generated by the prediction model 170 and using the market information 166. The updated rankings 168 can take into account the market information providing external predictions of the event.

The prediction model 170 can include a computer-implemented model capable of processing various data sources to generate strength-based rankings for a sporting event. The prediction model 170 can utilize any of a variety of machine learning, artificial intelligence, and/or neural network techniques to process historical player/team data and other contextual data for the event to derive the rankings for the event. The prediction model 170 can update the initial set of rankings using the market information as described herein.

The present system can include a single-match prediction approach, where the system can predict the final score of a match. The system can use the relative team strength (e.g., data-driven such as a power ranking or odds driven, or even manually adjusted). The model can include a multi-class classifier or could be a Bayesian approach. The model 170 can be trained using a standard supervised learning paradigm, using large amounts of historical data. The system can add more input features such as recent form (e.g., goals scored, conceded, specific player/talent available). The team strength can be calculated using both the futures market and the data-driven approach as described above.

The event simulation model 172 can include a computer-implemented model configured to perform a number of simulations of an upcoming event. The event simulation model 172 can use various sources of data, such as historical player/team data and the updated strength rankings to simulate the event to determine a likelihood of each player/team advancing to each stage of the event or winning the event. The predictions for the event can be generated based on the simulations generated by the event simulation model 172. For example, a predicted probability for a team advancing to a stage of the event can be based on a number of simulations in which the team advanced to the stage relative to a total number of simulations executed for the event. The event simulation model 172 can include a Monte-Carlo simulation model, for example.

The output model 174 can include a model configured to generate one or more outputs illustrating the predictions generated for the event. For example, the outputs can include a bracket view or table view illustrating each player/team and a probability of each player/team advancing to each stage of the event or winning the event. In some instances, the outputs can be interactive such that a client can select a player/team and highlight/view predictions for the player/team.

Client device 108 may be in communication with organization computing system 104 via network 105. Client device 108 may be operated by a user. For example, client device 108 may be a mobile device, a tablet, a desktop computer, or any computing system having the capabilities described herein. Users may include, but are not limited to, individuals such as, for example, subscribers, clients, prospective clients, or customers of an entity associated with organization computing system 104, such as individuals who have obtained, will obtain, or may obtain a product, service, or consultation from an entity associated with organization computing system 104.

Client device 108 may include at least application 132. Application 132 may be representative of a web browser that allows access to a website or a stand-alone application. Client device 108 may access application 132 to access one or more functionalities of organization computing system 104. Client device 108 may communicate over network 105 to request a webpage, for example, from web client application server 114 of organization computing system 104. For example, client device 108 may be configured to execute application 132 to access content managed by web client application server 114. The content that is displayed to client device 108 may be transmitted from web client application server 114 to client device 108, and subsequently processed by application 132 for display through a graphical user interface (GUI) of client device 108.

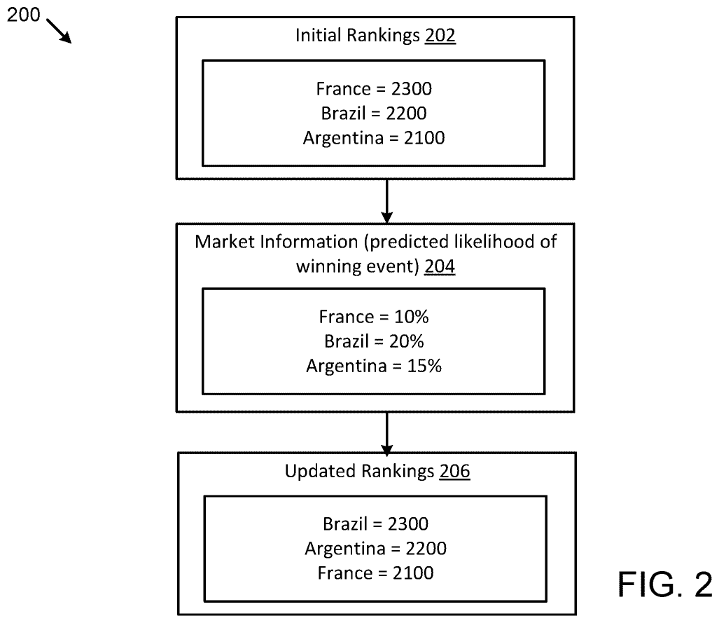

FIG. 2 is an example flow process 200 for updating an initial set of rankings using market information. As shown in FIG. 2, an initial set of rankings 202 can be generated for a sporting event. For example, for an upcoming event (e.g., the World Cup), prediction model 170 can generate an initial set of metrics (e.g., strength-based scores (or Elo scores)) for each team competing in the upcoming event. For instance, France can have a highest score of 2300, indicating a highest team strength, followed by Brazil at 2200 and Argentina at 2100.

As described above, the initial rankings can be modified using market information. Market information 204 can include predictions generated from various sources, such as other prediction models, sportsbooks, etc. For example, the market information 204 can include a predicted likelihood of winning the event. This can include a likelihood of France winning at 10%, Brazil winning at 20%, and Argentina winning at 15%. The market information 204 can either come from a single source or aggregated (e.g., averaged) across multiple sources. As can be seen, while France has a greatest score in the initial rankings 202, the market information 204 indicates that market sources have Brazil with a greatest chance of winning the event at 20%.

The prediction model 170 can update the initial rankings (e.g., 202) using the market information 204. The updated rankings 206 can provide an updated set of strength-based scores or other metrics ranking a relative strength of each team for the upcoming event. For example, the updated rankings 206 can include Brazil with a new highest score of 2300, followed by Argentina at 2200 and France at 2100. In some embodiments, the prediction model 170 can utilize one or more techniques, such as machine-learning techniques, to apply weights to the market information 204 and incorporate the weighted market information 204 into the initial rankings 202 to generate the updated rankings 206. For example, the model may assign higher weights to market information sources that have historically been more accurate. The specific metrics used for the strength-based scores in the rankings (e.g. the 2300, 2200, 2100 scores) can be generated by the prediction model and may represent a projected performance level for each team. Different scoring scales and formats for the strength metrics are possible.

The updated rankings as described herein can be used to simulate the event and/or generate various outputs depicting predictions of the event. The simulation of the event can include running a number of simulations (e.g., 100, 1000, 10,000 Simulations) of the event using player/team data and the updated rankings. The output of the simulations can include a number of times each team reaches a stage in the event (e.g., final 16, quarterfinal, semifinal, final, champion) in the simulations. The number of simulations can be configurable to allow for the tuning of the statistical significance of the simulations results. More simulations may provide higher confidence but may require more computing resources and time.

Responsive to simulating the event using the updated rankings, a number of outputs can be generated for the event.

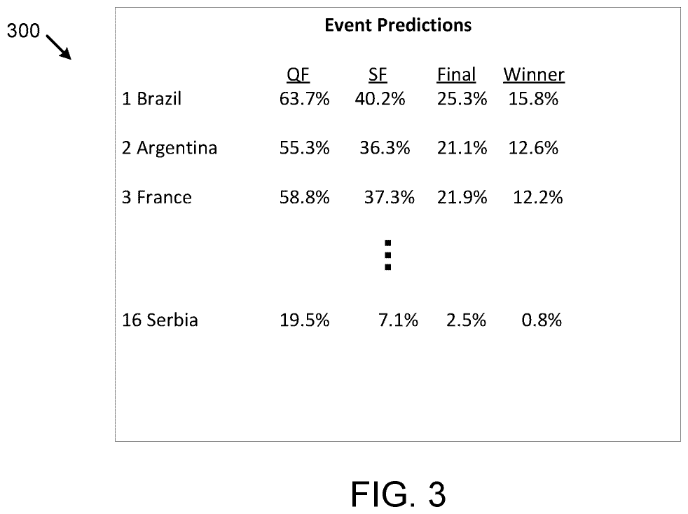

FIG. 3 is an example output 300 illustrating predictions for each team for an upcoming event. The output 300 can be generated based on the number of simulations ran for the event using the updated rankings.

As shown in FIG. 3, the output 300 can include predictions for the upcoming event for each team. For example, the predictions can include a predicted likelihood of each team (e.g., Brazil, Argentina, France, Serbia) making it to various stages (e.g., a quarterfinal (QF), semi-final (SF), final, and a winner) of the event. Further, as can be shown in the example in FIG. 3, the updated rankings can be largely indicative of the predicted results of each team. For instance, if Brazil has a highest updated ranking of team strength, Brazil can have a highest probability of making a quarterfinal (e.g., at 63.7%). In contrast, another team (e.g., Serbia) in this example can have a lowest probability of being a winner of the event (e.g., 0.8%) due to the updated rankings. The output 300 can provide various insights into the outcome of the simulation using the updated rankings. The output 300 may be dynamically updated as new market information becomes available leading up to the event. This allows the prediction to remain current and reflect the latest insights from the market. In some embodiments, the output 300 can include additional details beyond just the likelihood of advancing to each stage. For example, it may include predicted scored, expected opponents in each round, or highlight matchups where an upset is more likely based on the updated rankings.

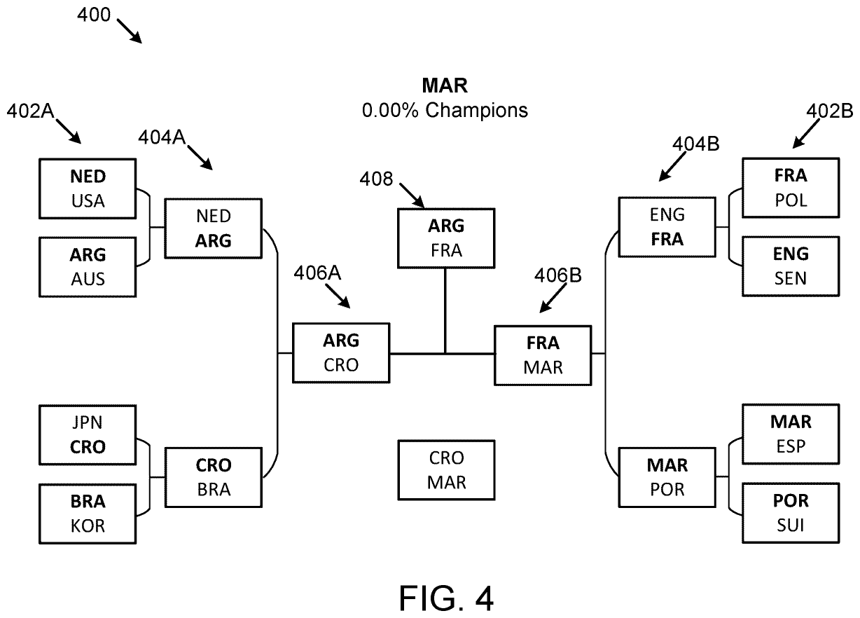

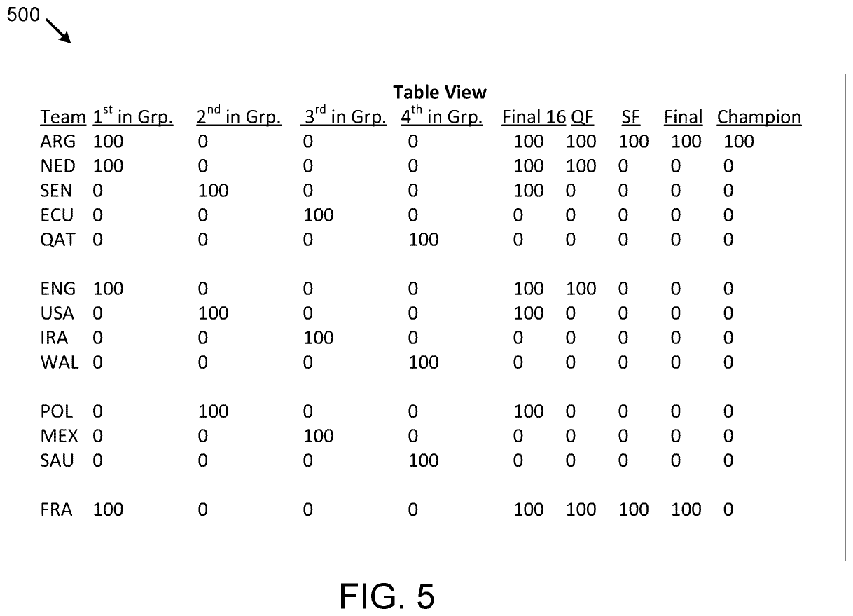

Further, the predictions and rankings provided by the prediction model 170. For example, rankings and outputs as described herein can be provided as part of an analysis platform (or website). FIGS. 4-5 provide various outputs capable of being shown as part of an analysis platform.

FIG. 4 provides a first example output 400 of features of an event. As shown in FIG. 4, a bracket view can depict each team in an event as part of a bracket. For example, brackets can depict a round of 16 402A, 402B, a quarterfinal 404A, 404B, a semifinal 406A, 406B, and a final 408. The output 400 can further depict a percentage of each team winning the tournament. In some instances, the output 400 can depict a predicted winning percentage for each game and for winning the tournament for a specified team. In some embodiments, the bracket view in output 400 may be an interactive visualization, enabling users to explore different paths and scenarios. For example, a user could select a specific team and see how the probabilities for other teams change based on that team advancing or being eliminated. In some embodiments, the bracket view can include additional information beyond just the winning percentages. For example, it may display predicted scores for each game, highlight potential upset alerts, or indicate the strength of each team's path to the championship based on their opponent's rankings and/or predicted opponent's rankings. The bracket view can be updated in real-time as games are played and outcomes are determined, enabling users to see how predictions evolve over the course of the tournament. Output 400 can include options to customize the view, such as focusing on a specific region of the bracket, filtering for specific teams, adjusting the level of details shown, or the like. In some embodiments, the bracket view can used to facilitate user interaction and engagement, such as through bracket challenges or fantasy sports integration. For example, users can make their own predictions and compare them to the model's outputs.

FIG. 5 provides a second example output 500 of features of an event. As shown in FIG. 5, a probability of each team making each stage in an event can be depicted in a table format. In some instances, the table view can include a prediction for each team to each rank based on the updated rankings as described herein. The table view in output 500 provides an alternative visualization to the bracket view, allowing users to quickly compare the probabilities for multiple teams across different stages of the tournament. The table can be sorted and filtered based on various criteria, such as by stage, by team, or by probability. This may enable users to easily identify the teams with the highest chances of advancing to each round.

In some embodiments, the table view can include additional columns beyond just the probabilities for each stage. For example, it may include the current ranking of each team, their initial ranking at the start of the tournament, or their change in ranking over the course of the tournament. It could also include other relevant statistics, such as each team's record, points scored, or key players. The table view can be exported to various formats, such as CSV or Excel, to allow users to perform their own analysis or integrate the data into other tools. This enhances the flexibility and usefulness of the output. Output 500 can be integrated with other views, such as the bracket view from output 400, to provide a comprehensive dashboard for exploring the tournament predictions. Users can switch between different visualizations to gain insights from multiple perspectives.

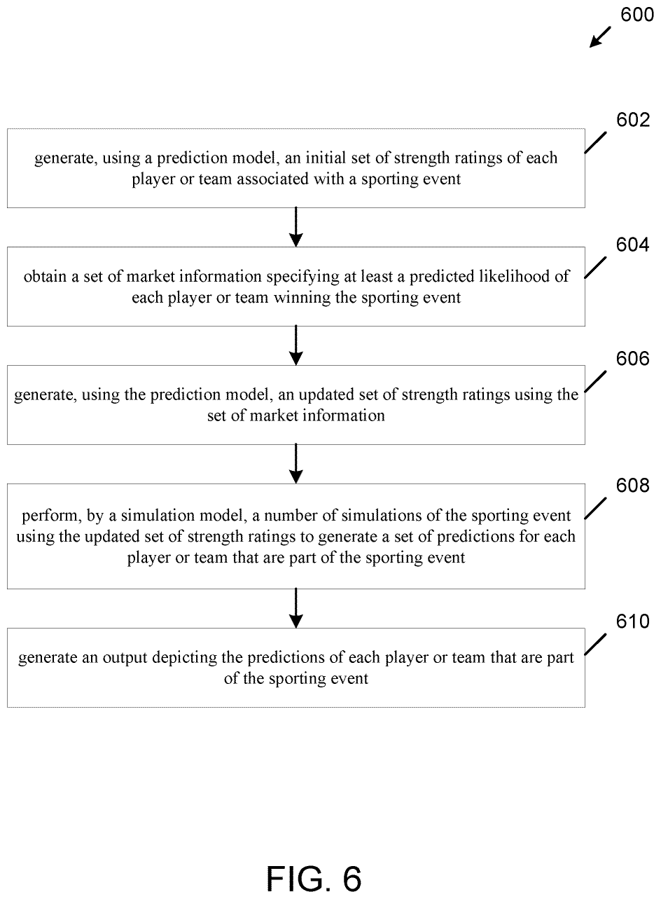

FIG. 6 is a flow diagram 600 of an example method of updating a set of strength-based ratings for a sporting event using market information. The method can be performed by a computing system as described herein.

At step 602, prediction model 170 may generate an initial set of strength ratings of each player or team associated with a sporting event. In some instances, each of the initial set of strength ratings include a metric indicating a predicted strength of each player or team that are part of the sporting event. The initial set of strength ratings can be generated at least based on historical player and team data. The prediction model 170 can be configured to automatically detect upcoming sporting events based on data feeds or user input (for example, based on a provided schedule, or by receiving one of more broadcast schedules and identifying one or more sporting events based on the broadcast schedule) and triggering the generation of initial strength ratings in advance of the event.

At step 604, prediction model 170 may obtain a set of market information specifying at least a predicted likelihood of each player or team winning the sporting event. In some instances, the market information is obtained by one or more sources of market information. The market information can be collected from a variety of sources, such as sportsbooks, betting exchanges, or prediction markets. The system can be configured to scrape this information from public websites or access it through private APIs.

In some embodiments, the market information is obtained by multiple sources of market information. The method can further include combining data from each of the multiple sources of market information to generate the predicted likelihood of each player or team winning the sporting event.

At step 606, prediction model 170 may generate an updated set of strength ratings using the set of market information. The updated set of strength ratings can be modified based on the set of market information to take into account any differences between the initial strength ratings and a probability of each team winning the sporting event provided by the market sources.

In some embodiments, the prediction model 170 is configured to employ various techniques to update the initial strength ratings, such as Elo ratings, using the obtained market information 166. One approach is to rearrange the initial rankings 164 to align with the implied ordering from the futures market information 166. By way of example, as shown in FIG. 2, the prediction model 170 includes an initial set of Elo rankings 164 for a set of team, such as the top three teams as shown, the initial set of Elo rankings 164 including: France—Elo: 2300; Brazil—Elo: 2200; Argentina—Elo: 2100.

In some embodiments, the prediction model 170 is configured to obtain futures market information 166, the futures market information 166 implying the following likelihoods of each team winning the tournament, such as: Brazil—20%; Argentina—15%; and France—10%. In some embodiments, to update the Elo ratings, the prediction model 170 is configured to rearrange the initial set of Elo rankings 164 to match the market-implied ordering, generating an updated set of Elo rankings 168, such as: Brazil—Elo: 2300; Argentina—Elo: 2200; and France—Elo: 2100.

In some embodiments, rearranging the initial set of Elo rankings 164 using the futures market information 166 enables the updated set of Elo rankings 168 to be consistent with the market consensus, while preserving the relative differences between the teams' Elo scores, and/or a relative spread and/or a relative maximum and minimum scores. In some embodiments, the prediction model 170 is configured to apply additional weighting or scaling factors when rearranging the initial set of Elo ratings 164. For example, the prediction model 170 can be configured to consider the magnitude of the differences in market probabilities from the futures market information 166, not just the ordering. Applying additional weighting or scaling factors allows the updated set of Elo ratings 168 to more precisely reflect the market's view of the relative strengths of the teams.

At step 608, the simulation model 172 may perform a number of simulations of the sporting event using the updated set of strength ratings to generate a set of predictions for each player or team that are part of the sporting event. In some instances, the set of predictions for each player or team that are part of the sporting event include, for each player or team, a predicted likelihood of the player or team advancing to each stage of the sporting event and/or the player or team winning the sporting event.

In some instances, the set of predictions for each player or team that are part of the sporting event are based on each player or team advancing to each stage of the sporting event or winning the sporting event in each of the number of simulations of the sporting event.

In some embodiments, the simulation model 172 is configured to utilize a simulation method, such as a Monte Carlo simulation technique to perform the simulations of the sporting event. The Monte Carlo simulation technique involves generating a large number of random scenarios based on the updated set of strength ratings 168 and the rules and structure of the sporting event. Each simulation can be run independently, with the outcomes tracked and aggregated to generate the set of predictions.

In some embodiments, the simulation model 172 is configured to account for various factors that can impact the outcome of the sporting event, such as home field advantage, weather conditions, player injuries, or the like. These factors can be incorporated into the simulation model 172 as adjustments to the strength ratings or as additional variables that influence the simulation outcomes.

In some embodiments, the simulation model 172 is configured to generate intermediate results and update the set of predictions dynamically as the simulations are being performed. This allows for real-time monitoring of the simulation progress and enables early termination of the simulations if certain convergence criteria are met.

In some embodiments, the simulation model 172 is configured to store the individual simulation results in a database or data store, allowing for subsequent analysis and visualization of the simulation outcomes. The stored simulation results can be used to generate various statistical measures, such as confidence intervals, probability distributions, or the like, to provide additional insights into the set of predictions.

In some embodiments, the simulation model 172 is configured to incorporate user-defined parameters or settings that control the behavior and output of the simulations. For example, users may be able to specify the number of simulations to run, the level of detail in the output predictions, or specific scenarios to simulate, such as upset conditions or player matchups.

At step 610, output model 174 can generate an output depicting the predictions of each player or team that are part of the sporting event. In some instances, the output includes an illustration of a bracket depicting an initial placement of each player or team in the sporting event, The output can further display the predictions of each player or team advancing to each stage of the sporting event or winning the sporting event. In some instances, the output includes a table of each player or team in the sporting event and the predictions of each player or team advancing to each stage of the sporting event or winning the sporting event.

In some embodiments, after generating the initial output predictions, the system is configured to allow for manual adjustments to the strength ratings based on user input or expert knowledge. For example, if the initial predictions lead to values that are deemed too low for a particular player or team, such as France, the system can be configured to manually increase France's Elo rating to a higher value, such as 2150.

In some embodiments, the output model 174 is configured to regenerate the predictions and update the visualizations in real-time based on the manual adjustments to the strength ratings. This allows users to interactively explore different scenarios and assess the impact of specific rating changes on the predicted outcomes.

In some embodiments, the output model 174 is configured to track and store the manual adjustments made to the strength ratings, along with the corresponding updated predictions. This enables the system to maintain a record of the changes and their effects, facilitating future analysis and refinement of the prediction model 170.

In some embodiments, the process of updating the strength ratings and generating predictions may be iterative. The simulation model 172 can be configured to run the simulations using the updated set of strength ratings 168, and the output model 174 can generate the resulting win probabilities for each player or team. The system can then compare these simulated win probabilities against the market-predicted probabilities obtained from the futures market information 166. If there are discrepancies between the simulated probabilities and the market probabilities, the system can be configured to make further adjustments to the strength ratings, either manually or automatically. For example, if the simulated win probability for a particular team, such as France, is lower than the market-predicted probability, the system can increase France's Elo rating by a certain amount, which may be a pre-determined amount, a weighted amount, or algorithmically based on one or more factors, such as the original Elo rating of the team, the relative Elo ratings of other teams in the simulation, one or more historical adjustments, and the like. The adjusted strength ratings can then be fed back into the simulation model 172, and the simulations can be run again. This iterative process can continue until the simulated win probabilities converge with the market-predicted probabilities, indicating that the strength ratings have been optimally adjusted to reflect the market information. The final converged strength ratings can be considered as the Elo scores that best align with the market consensus while preserving the relative differences between the teams' original ratings.

### Computing System Overview

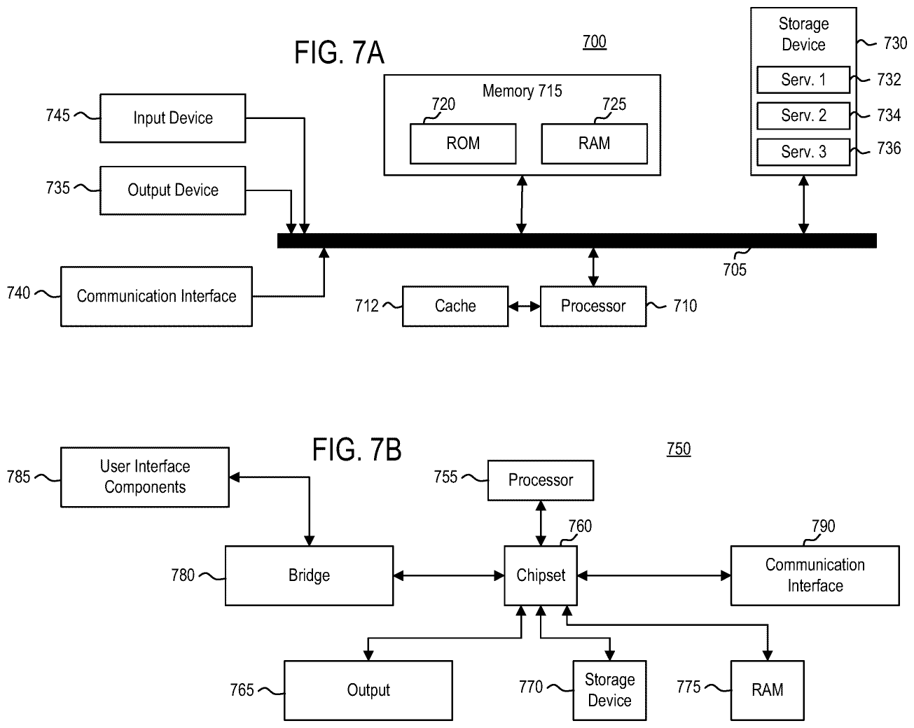

FIG. 7A illustrates a system bus computing system 700, according to example embodiments. System 700 may be representative of at least a portion of organization computing system 104. One or more components of system 700 may be in electrical communication with each other using a bus 705. System 700 may include a processing unit (CPU or processor) 710 and a system bus 705 that couples various system components including the system memory 715, such as read only memory (ROM) 720 and random-access memory (RAM) 725, to processor 710. System 700 may include a cache of high-speed memory connected directly with, in close proximity to, or integrated as part of processor 710. System 700 may copy data from memory 715 and/or storage device 730 to cache 712 for quick access by processor 710. In this way, cache 712 may provide a performance boost that avoids processor 710 delays while waiting for data. These and other modules may control or be configured to control processor 710 to perform various actions. Other system memory 715 may be available for use as well. Memory 715 may include multiple different types of memory with different performance characteristics. Processor 710 may include any general-purpose processor and a hardware module or software module, such as service 1 732, service 2 734, and service 3 736 stored in storage device 730, configured to control processor 710 as well as a special-purpose processor where software instructions are incorporated into the actual processor design. Processor 710 may essentially be a completely self-contained computing system, containing multiple cores or processors, a bus, memory controller, cache, etc. A multi-core processor may be symmetric or asymmetric.

To enable user interaction with the system 700, an input device 745 may represent any number of input mechanisms, such as a microphone for speech, a touch-sensitive screen for gesture or graphical input, keyboard, mouse, motion input, speech and so forth. An output device 735 may also be one or more of a number of output mechanisms known to those of skill in the art. In some instances, multimodal systems may enable a user to provide multiple types of input to communicate with system 700. Communications interface 740 may generally govern and manage the user input and system output. There is no restriction on operating on any particular hardware arrangement and therefore the basic features here may easily be substituted for improved hardware or firmware arrangements as they are developed.

Storage device 730 may be a non-volatile memory and may be a hard disk or other types of computer readable media which may store data that are accessible by a computer, such as magnetic cassettes, flash memory cards, solid state memory devices, digital versatile disks, cartridges, random access memories (RAMs) 725, read only memory (ROM) 720, and hybrids thereof.

Storage device 730 may include services 732, 734, and 736 for controlling the processor 710. Other hardware or software modules are contemplated. Storage device 730 may be connected to system bus 705. In one aspect, a hardware module that performs a particular function may include the software component stored in a computer-readable medium in connection with the necessary hardware components, such as processor 710, bus 705, output device 735, and so forth, to carry out the function.

FIG. 7B illustrates a computer system 750 having a chipset architecture that may represent at least a portion of organization computing system 104. Computer system 750 may be an example of computer hardware, software, and firmware that may be used to implement the disclosed technology. System 750 may include a processor 755, representative of any number of physically and/or logically distinct resources capable of executing software, firmware, and hardware configured to perform identified computations. Processor 755 may communicate with a chipset 760 that may control input to and output from processor 755. In this example, chipset 760 outputs information to output 765, such as a display, and may read and write information to storage 770, which may include magnetic media, and solid-state media, for example. Chipset 760 may also read data from and write data to storage 775 (e.g., RAM). A bridge 780 for interfacing with a variety of user interface components 785 may be provided for interfacing with chipset 760. Such user interface components 785 may include a keyboard, a microphone, touch detection and processing circuitry, a pointing device, such as a mouse, and so on. In general, inputs to system 750 may come from any of a variety of sources, machine generated and/or human generated.

Chipset 760 may also interface with one or more communication interfaces 790 that may have different physical interfaces. Such communication interfaces may include interfaces for wired and wireless local area networks, for broadband wireless networks, as well as personal area networks. Some applications of the methods for generating, displaying, and using the GUI disclosed herein may include receiving ordered datasets over the physical interface or be generated by the machine itself by processor 755 analyzing data stored in storage 770 or 775. Further, the machine may receive inputs from a user through user interface components 785 and execute appropriate functions, such as browsing functions by interpreting these inputs using processor 755.

It may be appreciated that example systems 700 and 750 may have more than one processor 710 or be part of a group or cluster of computing devices networked together to provide greater processing capability.

While the foregoing is directed to embodiments described herein, other and further embodiments may be devised without departing from the basic scope thereof. For example, aspects of the present disclosure may be implemented in hardware or software or a combination of hardware and software. One embodiment described herein may be implemented as a program product for use with a computer system. The program(s) of the program product define functions of the embodiments (including the methods described herein) and can be contained on a variety of computer-readable storage media. Illustrative computer-readable storage media include, but are not limited to: (i) non-writable storage media (e.g., read-only memory (ROM) devices within a computer, such as CD-ROM disks readably by a CD-ROM drive, flash memory, ROM chips, or any type of solid-state non-volatile memory) on which information is permanently stored; and (ii) writable storage media (e.g., floppy disks within a diskette drive or hard-disk drive or any type of solid state random-access memory) on which alterable information is stored. Such computer-readable storage media, when carrying computer-readable instructions that direct the functions of the disclosed embodiments, are embodiments of the present disclosure.

It will be appreciated to those skilled in the art that the preceding examples are exemplary and not limiting. It is intended that all permutations, enhancements, equivalents, and improvements thereto are apparent to those skilled in the art upon a reading of the specification and a study of the drawings are included within the true spirit and scope of the present disclosure. It is therefore intended that the following appended claims include all such modifications, permutations, and equivalents as fall within the true spirit and scope of these teachings.

What is claimed:

1. A method of updating a set of strength-based ratings for a sporting event using market information, the method comprising:
identifying an occurrence of a sporting event;
generating, using a prediction model, an initial set of strength ratings of each player or team associated with the sporting event responsive to identifying the occurrence of the sporting event;
obtaining a set of market information specifying at least a predicted likelihood of each player or team winning the sporting event;
generating, using the prediction model, an updated set of strength ratings using the set of market information;
simulating, via a simulation model, the sporting event using the updated set of strength ratings a plurality of times to generate a set of predictions for each player or team that are part of the sporting event; and
generating an output depicting the predictions of each player or team that are part of the sporting event.

2. The method of claim 1, wherein each of the initial set of strength ratings include a metric indicating a predicted strength of each player or team that are part of the sporting event, wherein the initial set of strength ratings are generated at least based on historical player and team data.

3. The method of claim 1, wherein the market information is obtained by one or more sources of market information.

4. The method of claim 3, wherein the market information is obtained by multiple sources of market information, and wherein the method further comprises:
combining data from each of the multiple sources of market information to generate the predicted likelihood of each player or team winning the sporting event.

5. The method of claim 1, wherein the set of predictions for each player or team that are part of the sporting event include, for each player or team, a predicted likelihood of the player or team advancing to each stage of the sporting event and/or the player or team winning the sporting event.

6. The method of claim 5, wherein the set of predictions for each player or team that are part of the sporting event are based on each player or team advancing to each stage of the sporting event or winning the sporting event in each of a number of simulations of the sporting event.

7. The method of claim 5, wherein the output includes an illustration of a bracket depicting an initial placement of each player or team in the sporting event, and wherein the output further displays the predictions of each player or team advancing to each stage of the sporting event or winning the sporting event.

8. The method of claim 5, wherein the output includes a table of each player or team in the sporting event and the predictions of each player or team advancing to each stage of the sporting event or winning the sporting event.

9. A system for updating a set of strength-based ratings for a sporting event using market information, the system comprising:
a processor; and
a memory having programming instructions stored thereon, which, when executed by the processor, performs one or more operations comprising:
identifying an occurrence of an upcoming sporting event;
generating, using a prediction model, an initial set of strength ratings of each player or team associated with the sporting event;
obtaining a set of market information specifying any of a predicted likelihood of each player or team advancing to a stage of the sporting event or winning the sporting event;
generating, using the prediction model, an updated set of strength ratings using the set of market information;
simulating, by a simulation model, the sporting event using the updated set of strength ratings to generate a set of predictions for each player or team that are part of the sporting event, wherein the set of predictions for each player or team that are part of the sporting event include, for each player or team, a predicted likelihood of the player or team advancing to each stage of the sporting event and/or the player or team winning the sporting event; and
generating an output depicting the predictions of each player or team that are part of the sporting event.

10. The system of claim 9, wherein the one or more operations further include:
identifying a change to a roster of one or more teams for the sporting event; and
responsive to identifying the change, modifying the initial set of strength ratings of each player or team associated with the sporting event to account for the change to the roster of the one or more teams for the sporting event.

11. The system of claim 9, wherein each of the initial set of strength ratings include a metric indicating a predicted strength of each player or team that are part of the sporting event, wherein the initial set of strength ratings are generated at least based on historical player and team data.

12. The system of claim 9, wherein the market information is obtained by multiple sources of market information, and wherein the operations further include:
combining data from each of the multiple sources of market information to generate the predicted likelihood of each player or team winning the sporting event.

13. The system of claim 9, wherein the output includes an illustration of a bracket depicting an initial placement of each player or team in the sporting event, and wherein the output further displays the predictions of each player or team advancing to each stage of the sporting event or winning the sporting event.

14. The system of claim 9, wherein the output includes a table of each player or team in the sporting event and the predictions of each player or team advancing to each stage of the sporting event or winning the sporting event.

15. A non-transitory computer readable medium including one or more sequences of instructions that, when executed by one or more processors, causes the one or more processors to perform processes including:
identifying an occurrence of an upcoming sporting event;
generating, using a prediction model, an initial set of strength ratings of each player or team associated with the sporting event;
obtaining market information from multiple sources specifying at least a predicted likelihood of each player or team winning the sporting event;
combining data from each of the multiple sources of market information to generate a combined predicted likelihood of each player or team winning the sporting event;
generating, using the prediction model, an updated set of strength ratings using the combined predicted likelihood of each player or team winning the sporting event;
simulating, by a simulation model, the sporting event using the updated set of strength ratings to generate a set of predictions for each player or team that are part of the sporting event; and
generating an output depicting the predictions of each player or team that are part of the sporting event.

16. The non-transitory computer readable medium of claim 15, wherein each of the initial set of strength ratings include a metric indicating a predicted strength of each player or team that are part of the sporting event, wherein the initial set of strength ratings are generated at least based on historical player and team data.

17. The non-transitory computer readable medium of claim 15, wherein the set of predictions for each player or team that are part of the sporting event include, for each player or team, a predicted likelihood of the player or team advancing to each stage of the sporting event and/or the player or team winning the sporting event.

18. The non-transitory computer readable medium of claim 17, wherein the set of predictions for each player or team that are part of the sporting event are based on each player or team advancing to each stage of the sporting event or winning the sporting event in each of a number of simulations of the sporting event.

19. The non-transitory computer readable medium of claim 17, wherein the output includes an illustration of a bracket depicting an initial placement of each player or team in the sporting event, and wherein the output further displays the predictions of each player or team advancing to each stage of the sporting event or winning the sporting event.

20. The non-transitory computer readable medium of claim 17, wherein the output includes a table of each player or team in the sporting event and the predictions of each player or team advancing to each stage of the sporting event or winning the sporting event.
